(19) United States
(12) Patent Application Publication
(10) Pub. No.: US 2025/0063243 A1
(43) Pub. Date: Feb. 20, 2025

(54) LIGHT DETECTING DEVICE AND ELECTRONIC DEVICE

(71) Applicant: SONY SEMICONDUCTOR SOLUTIONS CORPORATION, Kanagawa (JP)

(72) Inventors: Yutaro KOMURO, Kanagawa (JP); Yoshiki EBIKO, Kanagawa (JP); Tomohiro YAMAZAKI, Kanagawa (JP); Kyohei MIZUTA, Kanagawa (JP)

(73) Assignee: SONY SEMICONDUCTOR SOLUTIONS CORPORATION, Kanagawa (JP)

(21) Appl. No.: 18/725,268

(22) PCT Filed: Nov. 16, 2022
(86) PCT No.: PCT/JP2022/042603

§ 371 Date: Jun. 28, 2024

(30) Foreign Application Priority Data
Jan. 6, 2022 (JP) 2022-000929

(51) Int. Cl. H04N 23/55; G02B 1/14; G02B 1/18; G02B 5/00; G02B 5/30; H04N 23/52

(52) U.S. Cl. CPC H04N 23/55; G02B 1/14; G02B 1/18; H04N 23/52; G02B 5/008; G02B 5/3058

(57) ABSTRACT

There is provided a light detecting device that can suppress corrosion of optical elements while suppressing upper layer color mixing. The light detecting device includes: a substrate on which a plurality of photoelectric conversion units are formed; a plurality of optical elements that are disposed on a rear surface side of the substrate; and a microlens array that is disposed on a rear surface side of the plurality of optical elements, and includes a plurality of microlenses. Furthermore, the optical element contains a metal material, and a surface on an optical element side of the microlens array is formed in contact with the rear surfaces of the optical elements so as to cover the rear surfaces and also serve as a protection film that suppresses corrosion of the metal material of the optical elements.

### TECHNICAL FIELD

The present technology (the technology according to the present disclosure) relates to a light detecting device and an electronic device.

### BACKGROUND ART

Conventionally, there is proposed, for example, a light detecting device that includes polarization units that allow a specific polarization component of incident light to transmit therethrough (see, for example, PTL 1). The light detecting device described in PTL 1 includes a plurality of polarization units, a protection film, and a plurality of microlenses laminated in this order on a semiconductor substrate including a plurality of photoelectric conversion units to suppress corrosion of the polarization units by the protection film.

### CITATION LIST

### Patent Literature

PTL 1: JP 2020-126882A

### SUMMARY

### Technical Problem

However, the protection film and the microlenses are laminated on a light receiving surface side of the polarization units in the light detecting device described in PTL 1, and therefore makes the height of a layer (hereinafter, also referred to as an “upper layer”) located on the light receiving surface side of the polarization units higher. Hence, when, for example, light is diagonally incident on the microlens of a certain pixel, the light diagonally travels in the upper layer and thereby is incident on the polarization units and the photoelectric conversion units of neighboring pixels, and therefore photomixing (hereinafter, also referred to as “upper layer color mixing) is likely to occur.

An object of the present technology is to provide a light detecting device and an electronic device that can suppress corrosion of optical elements.

### Solution to Problem

A light detecting device according to the present disclosure includes: (a) a substrate on which a plurality of photoelectric conversion units are formed; (b) a plurality of optical elements that are disposed on a light receiving surface side of a semiconductor substrate; and (c) a microlens array that is disposed on a light receiving surface side of the plurality of optical elements, and includes a plurality of microlenses that guide incident light to the photoelectric conversion units, (d) the optical element contains a metal material, and (e) a surface on an optical element side of the microlens array is formed in contact with light receiving surfaces of the optical elements so as to cover the light receiving surfaces and also serve as a protection film that suppresses corrosion of the metal material.

An electronic device according to the present disclosure includes: (a) a substrate on which a plurality of photoelectric conversion units are formed; (b) a plurality of optical elements that are disposed on a light receiving surface side of a semiconductor substrate; and (c) a microlens array that is disposed on a light receiving surface side of the plurality of optical elements, and includes a plurality of microlenses that guide incident light to the photoelectric conversion units, (d) the optical element contains a metal material, and (e) a surface on an optical element side of the microlens array is formed in contact with light receiving surfaces of the optical elements so as to cover the light receiving surfaces and also serve as a protection film that suppresses corrosion of the metal material.

### BRIEF DESCRIPTION OF DRAWINGS

FIG. 1 is a diagram illustrating the overall schematic configuration of a solid-state imaging device according to a first embodiment.

FIG. 2 is a diagram taken along line A-A in FIG. 1 and illustrating a cross-sectional configuration of the solid-state imaging device.

FIG. 3A is a diagram illustrating a planar structure of a light diffusion structure, and is a diagram illustrating a case where large 4×4 recess portions are formed as the light diffusion structure.

FIG. 3B is a diagram illustrating a planar structure of a light diffusion structure, and is a diagram illustrating a case where small 4×4 recess portions are formed as the light diffusion structure.

FIG. 3C is a diagram illustrating a planar structure of a light diffusion structure, and is a diagram illustrating a case where large 3×3 recess portions are formed as the light diffusion structure.

FIG. 3D is a diagram illustrating a planar structure of a light diffusion structure, and is a diagram illustrating a case where small 3×3 recess portions are formed as the light diffusion structure.

FIG. 4 is a diagram illustrating an enlarged cross-sectional structure of the optical element.

FIG. 5 is a diagram illustrating a cross-sectional configuration of the solid-state imaging device that includes a protection film.

FIG. 6A is a diagram illustrating a method for forming an optical element array and a microlens array, and is a diagram illustrating a state where a light shielding film is formed.

FIG. 6B is a diagram illustrating the method for forming the optical element array and the microlens array, and is a diagram illustrating a state where a flattening film is formed.

FIG. 6C is a diagram illustrating the method for forming the optical element array and the microlens array, and is a diagram illustrating a state where a first material film is formed.

FIG. 6D is a diagram illustrating the method for forming the optical element array and the microlens array, and is a diagram illustrating a state where the optical element array is formed.

FIG. 6E is a diagram illustrating the method for forming the optical element array and the microlens array, and is a diagram illustrating a state where a second material film is formed.

FIG. 7 is a diagram illustrating an overall schematic configuration of the solid-state imaging device according to a modification example, and is a diagram illustrating a case where a wire grid polarizer is used as the optical element.

FIG. 8 is a diagram illustrating the overall schematic configuration of the solid-state imaging device according to the modification example, and is a diagram illustrating a case where a GMR filter is used as the optical element.

FIG. 9 is a diagram illustrating the overall schematic configuration of the solid-state imaging device according to the modification example, and is a diagram illustrating a case where the shapes of lens-shaped portions are a columnar type.

FIG. 10 is a diagram illustrating the overall schematic configuration of the solid-state imaging device according to the modification example, and is a diagram illustrating a case where the shapes of the lens-shaped portions are shapes formed by periodically disposing a plurality of microstructures.

FIG. 11 is a diagram illustrating the overall schematic configuration of the solid-state imaging device according to the modification example, and is a diagram illustrating a case where a metal light shielding film is disposed in a trench portion.

FIG. 12 is a diagram illustrating the overall schematic configuration of the solid-state imaging device according to the modification example, and is a diagram illustrating a case where groove portions are used as the light diffusion structure.

FIG. 13A is a diagram illustrating a planar structure of a light diffusion structure, and is a diagram illustrating a case where a cross-shaped groove portion is formed as the light diffusion structure.

FIG. 13B is a diagram illustrating a planar structure of a light diffusion structure, and is a diagram illustrating a case where a *-shaped groove portion is formed as the light diffusion structure.

FIG. 13C is a diagram illustrating a planar structure of a light diffusion structure, and is a diagram illustrating a case where a III-shaped groove portion is formed as the light diffusion structure.

FIG. 13D is a diagram illustrating a planar structure of a light diffusion structure, and is a diagram illustrating a case where dot-shaped groove portions are formed as the light diffusion structure.

FIG. 14 is a diagram illustrating the overall schematic configuration of the solid-state imaging device according to the modification example, and is a diagram illustrating a case where the light diffusion structure is omitted.

FIG. 15 is a diagram illustrating an example of a schematic configuration of an imaging device that is an electronic device to which the present technology is applied.

### DESCRIPTION OF EMBODIMENTS

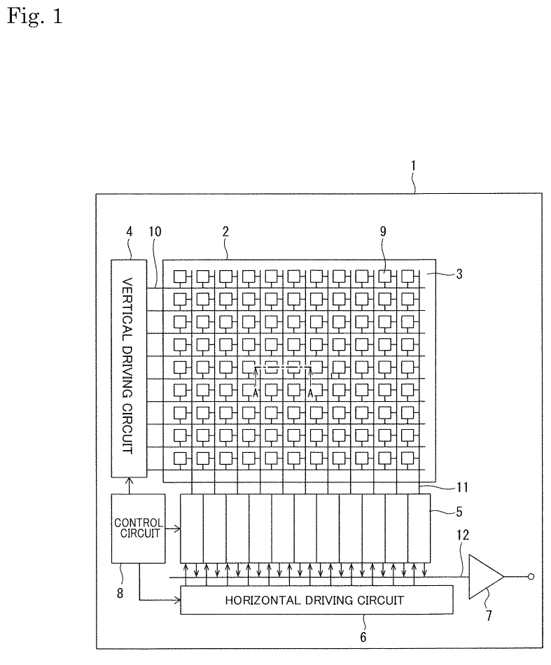

Hereinafter, examples of a light detecting device and an electronic device according to embodiments of the present disclosure will be described with reference to FIGS. 1 to 15. The embodiments of the present disclosure will be described in the following order. Note that the present disclosure is not limited to the following examples. In addition, the effects described in the present specification are merely illustrative and not limiting, and other effects may be obtained.
1. First Embodiment: Solid-State Imaging Device
1-1 Overall Configuration of Solid-State Imaging Device
1-2 Configuration of Main Parts
1-3 Method for Forming Optical Element Array and Microlens Array
1-4 Modification Example
2. Second Embodiment: Example of Application to Electronic Device

### 1. First Embodiment: Solid-State Imaging Device

### [1-1 Overall Configuration of Solid-State Imaging Device]

A solid-state imaging device 1 (a “light detecting device in a broad sense) according to the first embodiment of the present disclosure will be described. FIG. 1 is a diagram illustrating the overall schematic configuration of the solid-state imaging device 1 according to the first embodiment.

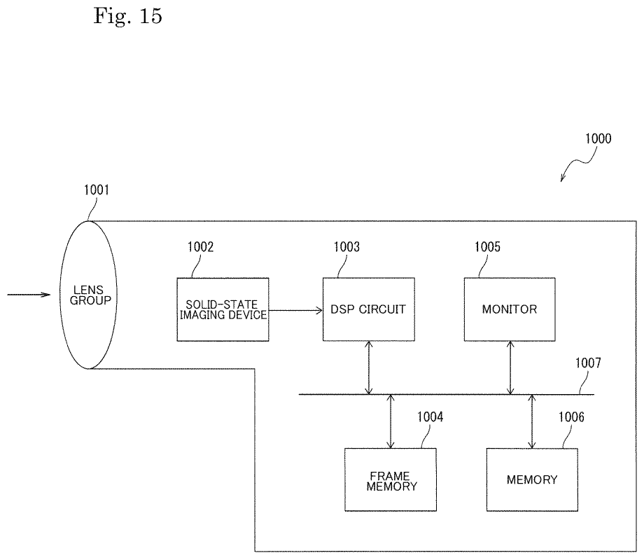

The solid-state imaging device 1 in FIG. 1 is a rear surface illuminated-type Complementary Metal Oxide Semiconductor (CMOS) image sensor. As illustrated in FIG. 15, the solid-state imaging device 1 (1002) captures image light (incident light) from a subject through a lens group 1001, converts a light amount of the incident light whose image is formed on an imaging surface into an electrical signal in units of pixels, and outputs the electrical signal as a pixel signal. As illustrated in FIG. 1, the solid-state imaging device 1 includes a substrate 2, a pixel region 3, a vertical driving circuit 4, column signal processing circuits 5, a horizontal driving circuit 6, an output circuit 7, and a control circuit 8.

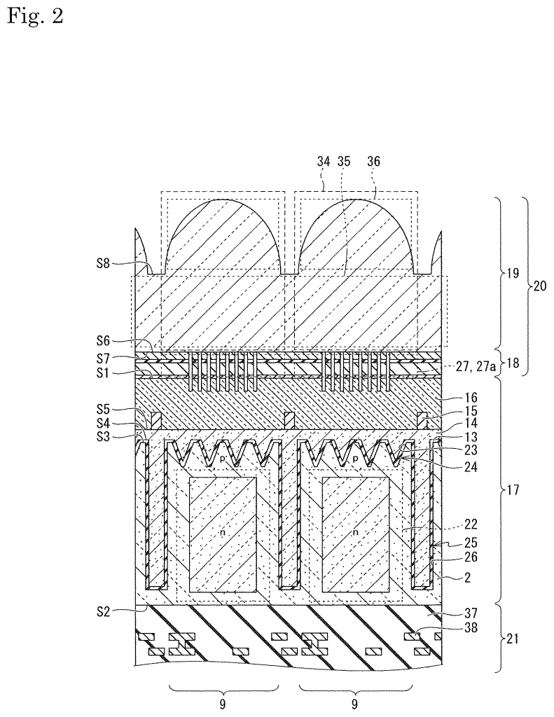

The pixel region 3 includes a plurality of pixels 9 disposed regularly in a two-dimensional array on the substrate 2. The pixel 9 includes a photoelectric conversion unit 22 illustrated in FIG. 2, and a plurality of pixel transistors. As the plurality of pixel transistors, for example, four transistors such as a transfer transistor, a reset transistor, an amplifier transistor, and a selection transistor can be adopted.

The vertical driving circuit 4 is configured of, for example, a shift register, selects a desired pixel drive wiring 10, supplies a pulse for driving the pixel 9 to the selected pixel drive wiring 10, and drives the respective pixels 9 in units of rows. That is, the vertical driving circuit 4 selectively scans the respective pixels 9 in the pixel region 3 sequentially in a vertical direction in units of rows, and supplies pixel signals based on signal charge generated according to the amount of received light in the photoelectric conversion units 22 of the respective pixels 9 to the column signal processing circuits 5 through vertical signal lines 11.

For example, the column signal processing circuit 5 is provided for each of the columns of unit pixels 9 to perform signal processing such as noise removal to signals output from a row of unit pixels 9 on a pixel column basis. For example, the column signal processing circuit 5 performs signal processing such as Correlated Double Sampling (CDS) for canceling pixel-specific fixed pattern noise and Analog-Digital (AD) conversion.

The horizontal driving circuit 6 is configured of, for example, a shift register, and sequentially outputs horizontal scanning pulses to the column signal processing circuits 5, selects the column signal processing circuits 5 in order, and causes pixel signals subjected to the signal processing to be output from the respective column signal processing circuits 5 to a horizontal signal line 12.

The output circuit 7 performs signal processing on the pixel signals sequentially supplied from the respective column signal processing circuits 5 through the horizontal signal line 12, and outputs resultant pixel signals. Examples of the signal processing include buffering, black level adjustment, column variation correction, and various digital signal processing.

The control circuit 8 generates a clock signal or a control signal as a reference for operations of the vertical driving circuit 4, the column signal processing circuit 5, the horizontal driving circuit 6, and the like on the basis of a vertical synchronization signal, a horizontal synchronization signal, and a master clock signal. In addition, the control circuit 8 outputs the generated clock signal or control signal to the vertical driving circuit 4, the column signal processing circuit 5, the horizontal driving circuit 6, and the like.

### [1-2 Configuration of Main Parts]

Next, a detailed structure of the solid-state imaging device 1 in FIG. 1 will be described. FIG. 2 is a diagram taken along line A-A in FIG. 1 and illustrating a cross-sectional configuration of the solid-state imaging device 1.

As illustrated in FIG. 2, the solid-state imaging device 1 includes a light reception layer 17 in which the substrate 2, a pinning film 13, an insulating film 14, a light shielding film 15, and a flattening film 16 are laminated in this order. In addition, a light reception layer 20 is disposed in which an optical element array 18 and a microlens array 19 are laminated in this order is disposed in a surface (hereinafter, referred to as a “rear surface S1”) on a flattening film 16 side of the light reception layer 17. Furthermore, a wiring layer 21 is disposed on a surface (hereinafter, also referred to as a “surface S2”) on a substrate 2 side of the light reception layer 17.

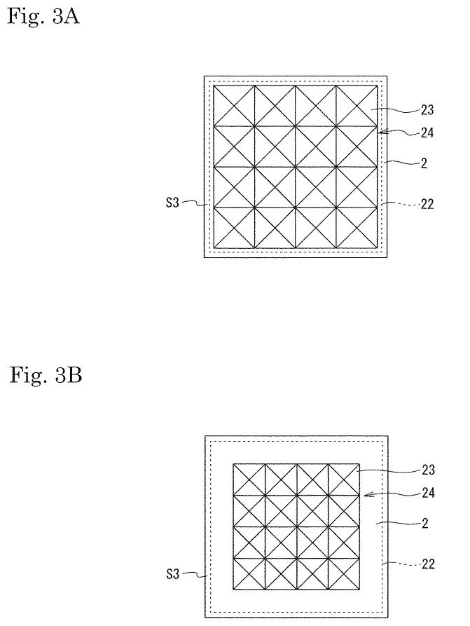

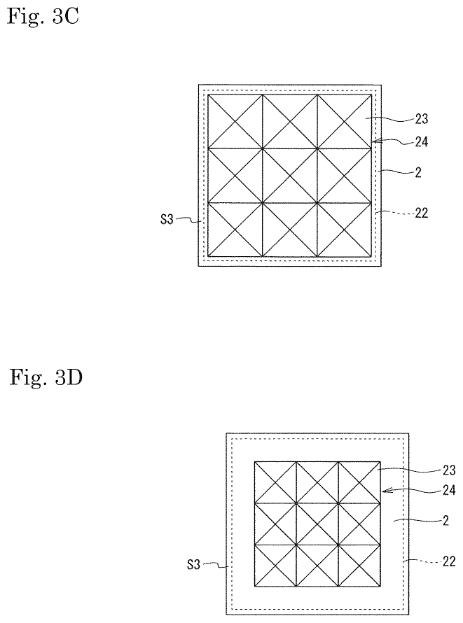

The substrate 2 is constituted of, for example, a semiconductor substrate made of silicone (Si) to form the pixel region 3. In the pixel region 3, a plurality of the pixels 9 each including the photoelectric conversion unit 22 and the plurality of pixel transistors (not illustrated) are disposed in a two-dimensional array (see FIG. 1). The photoelectric conversion unit 22 includes a p-type semiconductor region formed on an outer periphery side and an n-type semiconductor region formed on a center side, and forms a photodiode by pn junction. Thus, each photoelectric conversion unit 22 generates signal charge corresponding to the light amount of the incident light on the photoelectric conversion unit 22, and accumulates the generated signal charge in the n-type semiconductor region (charge accumulation region) of the photodiode. In addition, as illustrated in FIGS. 3A, 3B, 3C, and 3D, seen from a microlens array 19 side, a light diffusion structure 24 that includes a plurality of recess portions 23 of inverted pyramidal shapes disposed in a two-dimensional array is formed at each position that overlaps the photoelectric conversion unit 22 on a rear surface S3 side (light receiving surface side) of the substrate 2. Consequently, it is possible to increase a refraction amount of the incident light, reflect the incident light between pixel separating portions 25 and increase an optical path length, and photoelectrically convert light (e.g., near infrared light) of a long wavelength.

FIGS. 3A to 3D are diagrams illustrating a planar structure of the light diffusion structure 24, and FIG. 3A illustrates a case where, when seen from the microlens array 19 side, the 4×4 recess portions 23 are formed so as to overlap the entire photoelectric conversion unit 22. In addition, FIG. 3B illustrates a case where, when seen from the microlens array 19 side, the 4×4 recess portions 23 are formed so as to overlap the center portion of the photoelectric conversion unit 22. In addition, FIG. 3C illustrates a case where, when seen from the microlens array 19 side, the 3×3 recess portions 23 are formed so as to overlap the entire photoelectric conversion unit 22. In addition, FIG. 3D illustrates a case where, when seen from the microlens array 19 side, the 3×3recess portions 23 are formed so as to overlap the center portion of the photoelectric conversion unit 22.

In addition, the pixel separating portion 25 is formed between the neighboring photoelectric conversion units 22. The pixel separating portion 25 is formed in a grid shape so as to surround the surroundings of the photoelectric conversion units 22 when seen from the microlens array 19 side. The pixel separating portion 25 includes a trench portion 26 whose opening portion is formed in the rear surface S3 of the substrate 2 and whose bottom surface is formed in the substrate 2. The trench portion 26 is formed in a grid shape such that the inner side surfaces and the bottom surface form the outer periphery portion of the pixel separating portion 25. Note that, although the first embodiment has described the example where the bottom surface of the trench portion 26 is formed in the substrate 2, other configurations can be also used. For example, the trench portion 26 may be a through-groove penetrating the substrate 2, and a surface on the substrate 2 side of the wiring layer 21 may form the bottom surface of the trench portion 26.

The inner side surfaces and the bottom surface of the trench portion 26 are covered with the pinning film 13. In addition, the insulating film 14 is embedded in the trench portion 26. Consequently, when light having been incident on the photoelectric conversion unit 22 enters the pixel separating portion 25, it is possible to reflect the entering light through an interface between the insulating film 14 and the pinning film 13, and suppress photomixing that occurs when the light transmits through the pixel separating portion 25.

The pinning film 13 continuously covers an entire rear surface S3 side of the substrate 2, and the inner side surfaces and the bottom surface of the trench portion 26. As examples of a material of the pinning film 13, a high refractive index material film or a high dielectric film that can produce fixed charge and enhance pinning and has negative charge can be adopted. The examples of the material of the pinning film 13 include an oxide or a nitride containing at least one element of hafnium (Hf), aluminum (Al), zirconium (Zr), tantalum (Ta), and titanium (Ti). The insulating film 14 continuously covers an entire rear surface S4 side of the pinning film 13 (the entire light receiving surface side), and is embedded inside the trench portion 26. As examples of a material of the insulating film 14, an oxide film or the like that has a different refractive index from that of the pinning film 13 can be adopted. The examples of the material of the insulating film 14 include silicon oxide (SiO₂), silicon nitride (SiN), and silicon oxynitride (SiON).

The light shielding film 15 is formed in a grid shape to so as open the light receiving surfaces of the plurality of photoelectric conversion units 22 in part of a rear surface S5 side of the insulating film 14 (part of the light receiving surface side). That is, the light shielding film 15 is formed at a position that overlaps the pixel separating portion 25 formed in the grid shape seen from the microlens array 19 side. As examples of a material of the light shielding film 15, a material that can shield light can be adopted. The examples of the material of the light shielding film 15 include aluminum (Al), tungsten (W), and copper (Cu).

The flattening film 16 continuously covers the entire rear surface S5 side (entire light receiving surface side) of the insulating film 14 including the light shielding film 15. Accordingly, the rear surface S1 of the light reception layer 17 is a flat surface without unevenness. As a material of the flattening film 16, an organic material such as a resin can be used.

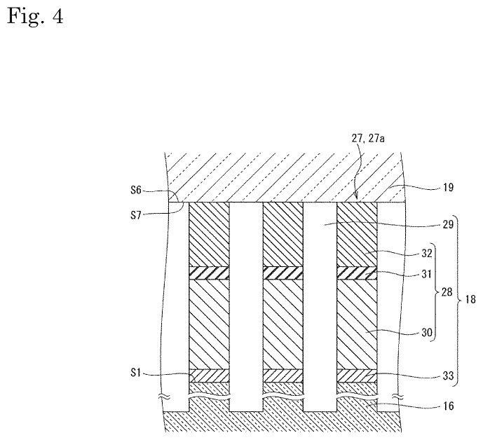

The optical element array 18 includes a plurality of optical elements 27 that are formed on the rear surface S5 side of the insulating film 14 and are disposed to meet the photoelectric conversion units 22. That is, the one optical element 27 is formed for the one photoelectric conversion unit 22. As the optical element 27, an optical element containing, for example, a metal material can be adopted. Examples of the metal material include aluminum (Al), copper (Cu), tungsten (W), titanium (Ti), tantalum (Ta), silicon (Si), platinum (Pt), and gold (Au). FIG. 4 is a diagram illustrating an enlarged cross-sectional structure of the optical elements 27. FIG. 4 illustrates a case where wire grid polarizers 27a are adopted as the optical elements 27. The wire grid polarizer 27a includes a plurality of belt-shaped conductors 28 that are disposed at predetermined pitches. As the belt-shaped conductor 28, a conductor (wire) formed in, for example, a linear shape or a cuboid shape can be adopted.

The free electrons in the belt-shaped conductor 28 vibrate following the electric field of light incident on the belt-shaped conductor 28, and radiate a reflective wave. Here, since the amplitude of the free electrons increases, the incident light in a direction vertical to a direction in which the plurality of belt-shaped conductors 28 are disposed, that is, a direction parallel to a longitudinal direction of the belt-shaped conductors 28 radiate more reflective light. Hence, the incident light parallel to the longitudinal direction of the belt-shaped conductors 28 is reflected without transmitting through the wire grid polarizer 27a. On the other hand, since vibration of the free electrons is limited and the amplitude thereof becomes little, the light vertical to the longitudinal direction of the belt-shaped conductors 28 radiates less reflective light from the belt-shaped conductor 28. Hence, the incident light vertical to the longitudinal direction of the belt-shaped conductors 28 is attenuated little by the wire grid polarizer 27a, and can transmit through the wire grid polarizer 27a.

The plurality of optical elements 27 (wire grid polarizers 27a) included in the optical element array 18 include a plurality of types of wire grid polarizers whose polarization directions are respectively different. Examples of the wire grid polarizers include four types of wire grid polarizers whose longitudinal directions of the belt-shaped conductors 28 differ by 45° in order. Consequently, each of the plurality of wire grid polarizers 27a allows the incident light vertical to the longitudinal direction of the belt-shaped conductors 28 to transmit therethrough, and allows the transmitting incident light to be incident on the corresponding photoelectric conversion unit 22.

Furthermore, a groove-shaped space (gap 29) whose side surface is formed by the belt-shaped conductor 28 and whose bottom surface is formed by the flattening film 16 is formed between the neighboring belt-shaped conductors 28. An opening portion of the gap 29 (groove) is closed by the microlens array 19. A gas such as air (whose refractive index is 1.0) is encapsulated in the gap 29. Consequently, it is possible to reduce the refractive index of the space between the belt-shaped conductors 28, so that it is possible to improve transmittances of the wire grid polarizers 27a. FIG. 4 illustrates a case where an end portion on the flattening film 16 side of the gap 29 reaches the inside of the flattening film 16.

FIG. 4 illustrates a case where each of the plurality of belt-shaped conductors 28 has a structure that a light reflection layer 30, an insulation layer 31, and a light absorption layer 32 are laminated in this order on the flattening film 16. An adhesion layer 33 that improves adhesion strength may be disposed between the light reflection layer 30 and the flattening film 16. As examples of a material of the adhesion layer 33, titanium (Ti) or titanium nitride (TiN) can be adopted.

The light reflection layer 30 is a layer for reflecting the incident light. Consequently, it is possible to reflect light in the direction vertical to an alignment direction of the belt-shaped conductors 28, that is, in a vibration direction parallel to the longitudinal direction of the belt-shaped conductors 28. As a material of the light reflection layer 30, for example, aluminum (Al) can be adopted.

The insulation layer 31 is a layer for protecting the light reflection layer 30 formed in advance when the solid-state imaging device 1 is manufactured. Furthermore, the insulation layer 31 is also a layer for adjusting the phase of light reflected by the light reflection layer 30. When the phase is adjusted, the film thickness of the insulation layer 31 is such a thickness that there is a phase difference of 180° between the phase of the light transmitting through the light absorption layer 32 and reflected in the light reflection layer 30 and the phase of the light reflected in the light absorption layer 32. Consequently, the light reflected by each of the light reflection layer 30 and the light absorption layer 32 cancels each other, so that the reflective light from the wire grid polarizer 27a is reduced. As the material of the insulation layer 31, for example, silicon oxide (SiO₂) can be adopted.

The light absorption layer 32 is a layer for absorbing the light reflected by the light reflection layer 30. Consequently, it is possible to reduce the reflective light from the wire grid polarizer 27a, and reduce noise such as flare caused by the reflective light. As a material of the light absorption layer 32, for example, a material whose extinction coefficient is not zero, that is, a metal or a conductor that has an absorption function can be adopted. Examples of the material of the light absorption layer 32 include copper (Cu), tungsten (W), titanium (Ti), tantalum (Ta), silicon (Si), platinum (Pt), gold (Au), molybdenum (Mo), chromium (Cr), nickel (Ni), iron (Fe), silver (Ag), germanium (Ge), tellurium (Te), and tin (Sn). In addition, silicide-based materials such as FeSi₂ (especially β-FeSi₂), MgSi₂, NiSi₂, BaSi₂, CrSi₂, and CoSi₂ can be also adopted. The film thickness of the light absorption layer 32 is thinned to reduce a decrease in the transmittance at a time when, for example, the incident light transmits.

The microlens array 19 includes a plurality of microlenses 34 that are formed on a rear surface S6 side (light incident surface side) of the optical element array 18, and are disposed to meet the photoelectric conversion units 22. That is, the one microlens 34 is formed for the one photoelectric conversion unit 22. Each of the plurality of microlenses 34 has a structure that a bottom portion 35 shared by the plurality of microlenses 34 and a lens-shaped portion 36 individually formed per microlens 34 are laminated in this order on the optical element array 18. The bottom portion 35 and the lens-shaped portion 36 are integrally formed by performing dry etching on a film-like member made of a predetermined material with a mask interposed therebetween.

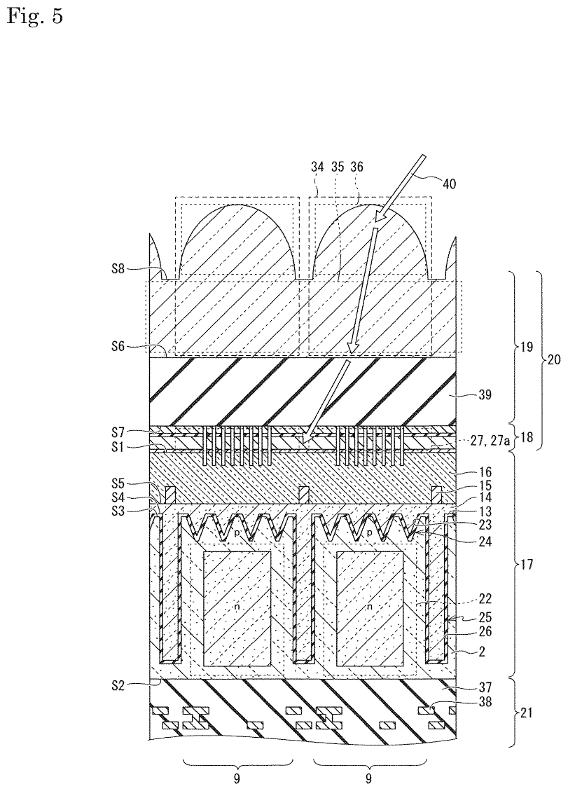

The bottom portion 35 is formed in a flat shape that continuously covers the entire rear surface S6 side (the entire light incident surface side) of the optical element array 18. A surface S7 (a surface on an optical element array 18 side) of the bottom portion 35 is in contact with the rear surface S6 (light receiving surface) of the optical element array 18 and covers the rear surface S6. Consequently, the bottom portion 35 also serves as a protection film (a protection film 39 illustrated in FIG. 5) that suppresses corrosion such as rust of the metal material contained in the wire grid polarizer 27a (belt-shaped conductor 28). Furthermore, the bottom portion 35 is disposed in contact with the rear surface S6 of the belt-shaped conductor 28, and closes an opening end on the microlens array 19 side of the space between the belt-shaped conductors 28 such that the gap 29 is left between the belt-shaped conductors 28.

The lens-shaped portion 36 is formed to meet the photoelectric conversion unit 22 on a rear surface S8 side (light receiving surface side) of the bottom portion 35. That is, the one lens-shaped portion 36 is formed for the one photoelectric conversion unit 22. As the shape of the lens-shaped portion 36, for example, a planar protrusion type whose one face is a planar face can be adopted. Each of the lens-shaped portions 36 condenses image light (incident light) from a subject, and more efficiently guide the condensed incident light to the inside of the corresponding photoelectric conversion unit 22 via the corresponding optical element 27.

Furthermore, as materials of the bottom portion 35 and the lens-shaped portion 36, for example, the same material can be adopted. For example, a material having the water vapor barrier property can be adopted. Examples of the material having the water vapor barrier property include materials whose water vapor transmission rate is 10⁻³ g/(m²·24 h) or less. Furthermore, a material of 10⁻⁶ g/(m²·24 h) or less is more preferable. An example of the water vapor transmission rate includes grams [g/(m²·24 h)] of water vapor per 1 m² in area that has transmitted in 24 hours. Consequently, it is possible to reduce moisture in air that transmits through the microlens 34 and enters a wire grid polarizer 27a side, and suppress corrosion of the belt-shaped conductors 28 due to the moisture in air. Examples of the material having the water vapor barrier property include silicon nitride (SiN), the silicon oxynitride (SiON), and the silicon carbonitride (SiCN). Consequently, the material contain nitrogen (N), so that it is possible to increase the density of the material and improve the water vapor barrier property. Furthermore, the silicon nitride (SiN) in particular has a large refractive index, so that it is also possible to appropriately condense light (e.g., near infrared light) of a long wavelength that is hard to bend.

The wiring layer 21 is formed on the surface S2 side of the substrate 2, and is configured to include an insulating interlayer film 37 and wirings 38 laminated as a plurality of layers with the insulating interlayer film 37 interposed therebetween. The wiring layer 21 drives the pixel transistors constituting each pixel 9 through the plurality of layers of wirings 38.

In the solid-state imaging device 1 having the above-described configuration, light is emitted from the rear surface S3 side of the substrate 2, the emitted light transmits through the microlenses 34 and the optical elements 27, and the transmitted light is photoelectrically converted by the photoelectric conversion units 22 to generate signal charges. Furthermore, the generated signal charge is output as a pixel signal on the vertical signal line 11 in FIG. 1 formed by the wiring 38 of the wiring layer 21.

Here, in a case of the structure that the protection film 39 (e.g., SiN film) that suppresses corrosion of the metal material contained in the wire grid polarizer 27a is disposed between the wire grid polarizer 27a and the microlens 34 separately from the microlens array 19 as illustrated in, for example, FIG. 5, the height of the layer (upper layer) located on the light receiving surface of the wire grid polarizer 27a becomes higher. Hence, when, for example, light 40 is diagonally incident on the microlens 34 of the certain pixel 9, the light 40 diagonally travels in the upper layer, thereby the light 40 is incident on the wire grid polarizers 27a and the photoelectric conversion units 22 of the neighboring pixels 9, and photomixing (upper layer color mixing) is likely to occur.

By contrast with this, according to the first embodiment, as illustrated in FIG. 2, the microlens array 19 is configured such that the surface (surface S7) on the wire grid polarizer 27a side is in contact with the rear surface S6 of the wire grid polarizer 27a and covers the rear surface S6, and also serves as the protection film that suppresses corrosion of the metal material contained in the wire grid polarizer 27a. Consequently, it is possible to prevent the height of the layer located on the rear surface S6 side of the wire grid polarizer 27a from becoming higher, and prevent the upper layer color mixing. In addition, the microlens array 19 can protect the wire grid polarizers 27a. Consequently, it is possible to suppress corrosion of the wire grid polarizers 27a (optical elements 27) while suppressing the upper layer color mixing.

In addition, compared to a case where, for example, the protection film 39 is disposed separately from the microlens array 19, it is possible to reduce the number of processes and suppress manufacturing cost at a time of manufacturing of the solid-state imaging device 1.

In addition, as the material of the microlens array 19, a material (e.g., silicon nitride) having the water vapor barrier property is used. Consequently, when air transmits through the microlens 34 from the light receiving surface side of the microlens 34 and enters the wire grid polarizer 27a side, it is possible to reduce moisture contained in the entering air, and suppress corrosion of the belt-shaped conductor 28 due to the moisture.

### [1-3 Method for Forming Optical Element Array and Microlens Array]

Next, a method for forming the optical element array 18 and the microlens array 19 will be described.

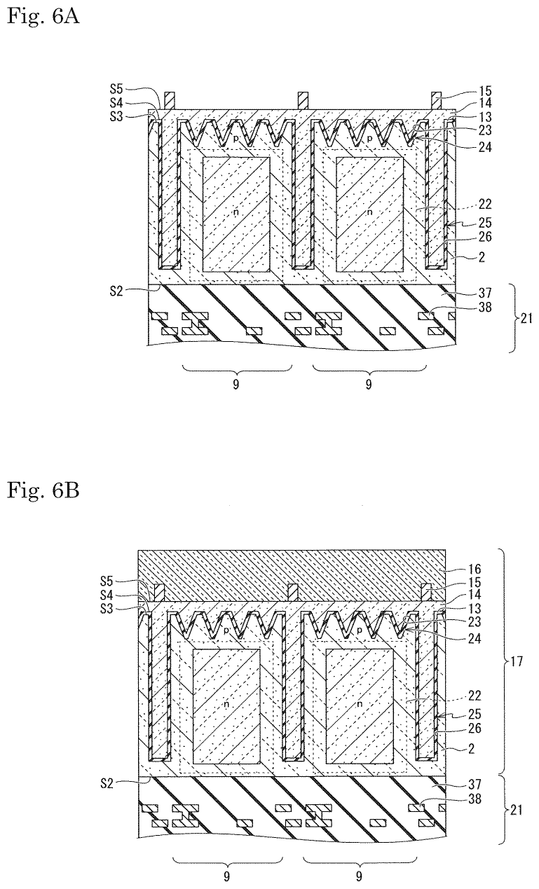

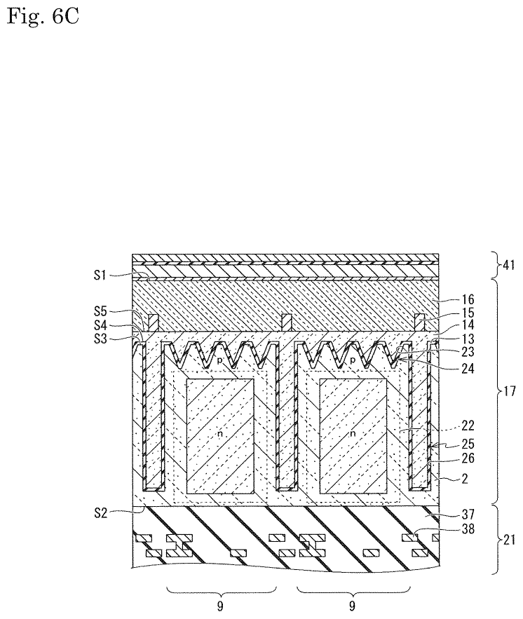

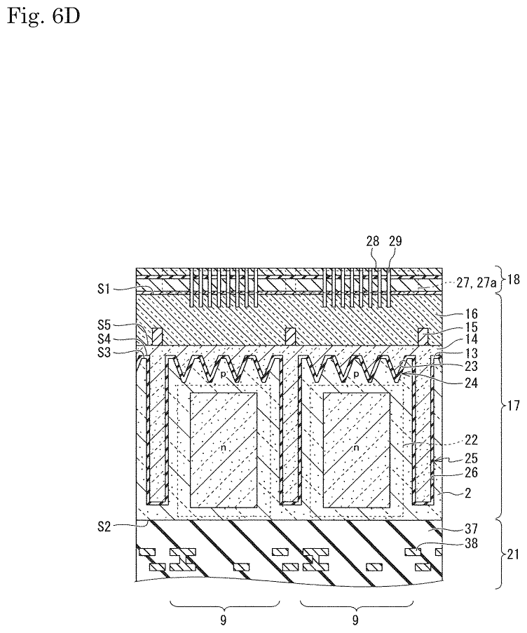

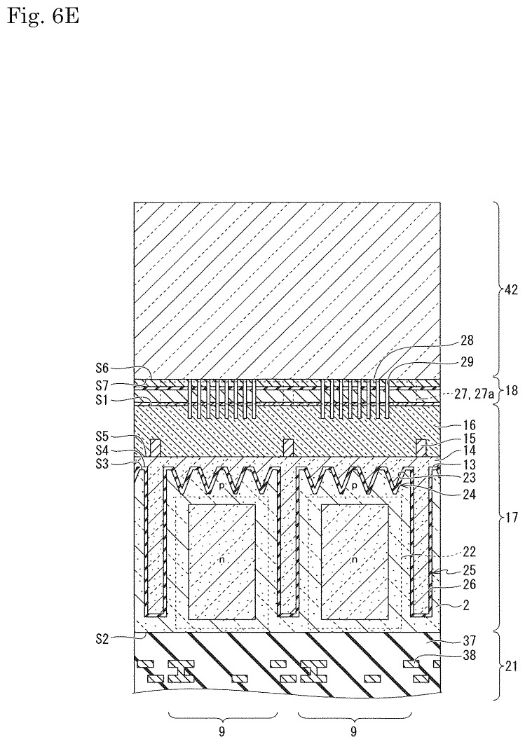

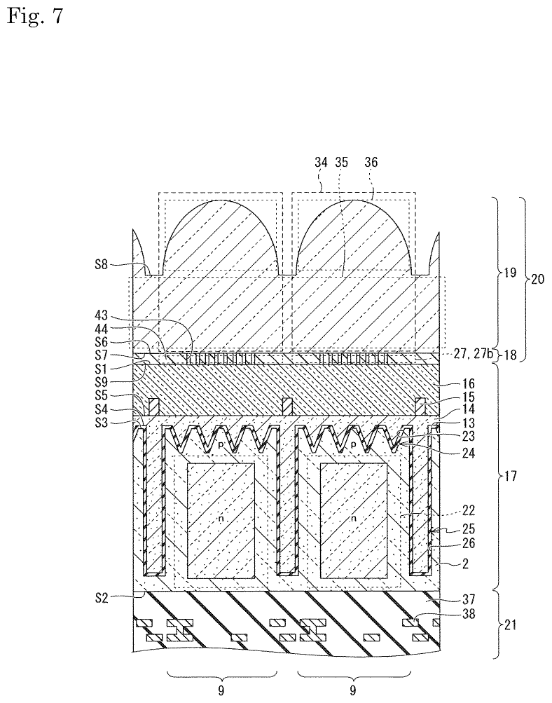

First, as illustrated in FIG. 6A, the trench portion 26, the pinning film 13, the insulating film 14, and the light shielding film 15 are formed on the rear surface S3 of the substrate 2. Next, as illustrated in FIG. 6B, the flattening film 16 is formed on the rear surface S5 of the insulating film 14 so as to continuously cover the entire rear surface S5 side. Next, as illustrated in FIG. 6C, a first material film 41 (metal film) made of the material of the belt-shaped conductor 28 of the wire grid polarizer 27a is formed. In FIG. 6C, the first material film 41 is a film of a multilayer structure that the material of the light reflection layer 30, the material of the insulation layer 31, and the material of the light absorption layer 32 are laminated.

Next, dry etching is performed to form the gaps 29 of the wire grid polarizers 27a in the first material film 41 and form the belt-shaped conductors 28 (wire grid polarizers 27a), and form the optical element array 18 as illustrated in FIG. 6D. Next, as illustrated in FIG. 6E, a second material film 42 made of the material of the microlens array 19 is formed on the rear surface S6 of the optical element array 18. As a method for forming the second material film 42, for example, Physical Vapor Deposition (PVD) or Chemical Vapor Deposition (CVD) can be used.

Particularly, considering to make it difficult for SiN or the like to enter the gap 29 and to close the opening end of the gap 29, it is more preferable to adopt the PVD method that has poor coverage for sidewall surfaces and a bottom surface. Next, dry etching is performed to form the bottom portions 35 and the lens-shaped portions 36 in the second material film 42 and form the microlens array 19 as illustrated in FIG. 2. Consequently, the optical element array 18 and the microlens array 19 are formed.

### [1-4 Modification Example]

(1) Note that, although the first embodiment has described the example where the wire grid polarizer 27a is used as the optical element 27, other configurations can be also adopted. As illustrated in, for example, FIG. 7, a configuration may be employed where a plasmon filter 27b is used as the optical element 27. The plasmon filter 27b is a filter that uses surface plasmon resonance. As illustrated in FIG. 7, the plasmon filter 27b includes a metal film 44 that includes a plurality of holes 43 formed in a two-dimensional array. The plasmon filter 27b converts light having been incident on the light receiving surface (rear surface S6) of the metal film 44 into surface plasmon, and the converted surface plasmon resonates in the rear surface S6 of the metal film 44. A component that satisfies a predetermined structure condition and a physical property condition among the resonated surface plasmon passes through the holes 43, and reaches a surface (surface S9) on an opposite side to the rear surface S6 of the metal film 44. The surface plasmon having reached the surface S9 is converted into light again in the surface S9 of the metal film 44, and is emitted. Thus, light of a predetermined band transmits through the plasmon filter 27b. As a material of the metal film 44, for example, aluminum (Al) can be adopted.

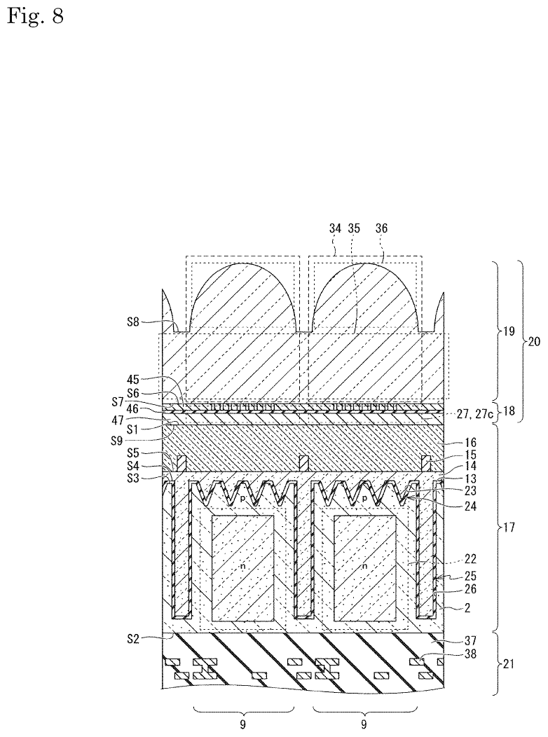

Meanwhile, although an example where light is split according to the propagation type surface plasmon in the plasmon filter 27b has been described here, it is also possible to split light according to the same principle in a localized surface plasmon resonance filter (localized surface plasmon resonance filter) having a structure in which nanoscale metallic columnar structures (metal nanostructures) are periodically disposed.
(2) In addition, there may be employed a configuration where a Guided Mode Resonance (GMR) filter 27c is used as the optical element 27 as illustrated in, for example, FIG. 8. The GMR filter 27c is a filter that uses waveguide mode resonance. The GMR filter 27c includes a diffraction grating 45, a clad layer 46, and a core layer 47. The diffraction grating 45, the clad layer 46, and the core layer 47 are laminated in this order from an incidence direction of light. The GMR filter 27c allows light of a predetermined narrow band to transmit through by light diffraction of the diffraction grating 45, and trapping of light of a specific wavelength in the core layer 47 by a clad/core structure and the transmission property of the light of the specific wavelength of the clad/core structure.

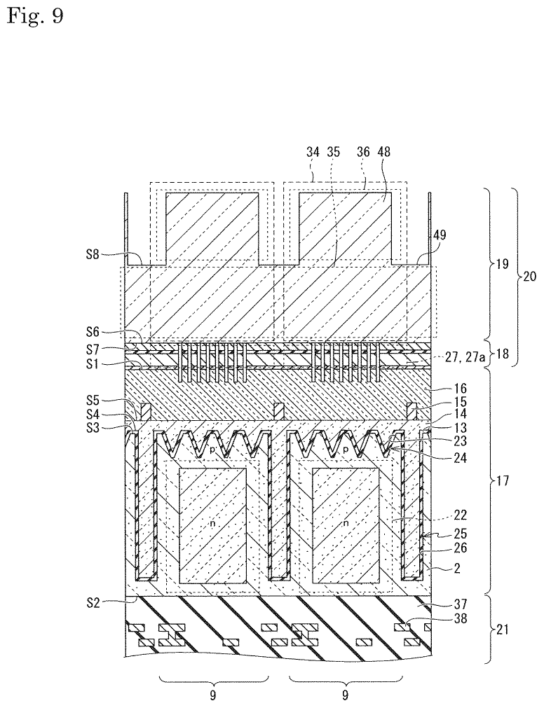

Here, a refractive index Na of the microlens array 19, a refractive index Nb of the clad layer 46, a refractive index Nc of the core layer 47, and a refractive index Nd of the flattening film 16 are set to Nc>Nb or Nd>Na. As a material of the diffraction grating 45, for example, aluminum (Al) can be adopted. In addition, as the material of the clad layer 46, for example, silicon oxide (SiO₂) can be adopted. In addition, as the material of the core layer 47, for example, silicon nitride (SiN), tantalum dioxide (TaO₂), or titanium oxide (TiO₂) can be adopted.
(3) In addition, although the first embodiment has described the example where the planar protrusion type is used as the shape of the lens-shaped portion 36, other configurations can be also adopted. For example, a configuration may be employed where a columnar type is used as the shape of the lens-shaped portion 36 as illustrated in FIG. 9 (BOX lens). The lens-shaped portion 36 includes, for example, a protrusion portion 48 that is formed on the photoelectric conversion unit 22, and a recess portion 49 that is formed on the pixel separating portion 25. As the shape of the protrusion portion 48, for example, a rotational symmetrical shape such as a circular columnar shape, and an asymmetrical shape such as a regular rectangular prism shape can be adopted. Furthermore, as the shape of the recess portion 49, for example, a groove shape whose protrusion portion 48 is a sidewall surface can be adopted. The top surface of the protrusion portion 48 and the bottom surface of the recess portion 49 are parallel to the rear surface S3 of the substrate 2. In addition, the refractive index of the microlens 34 is larger than the refractive index of air.

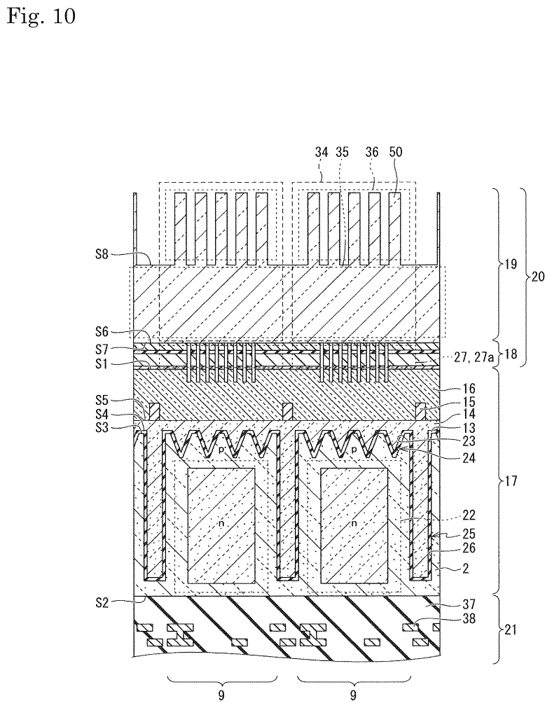

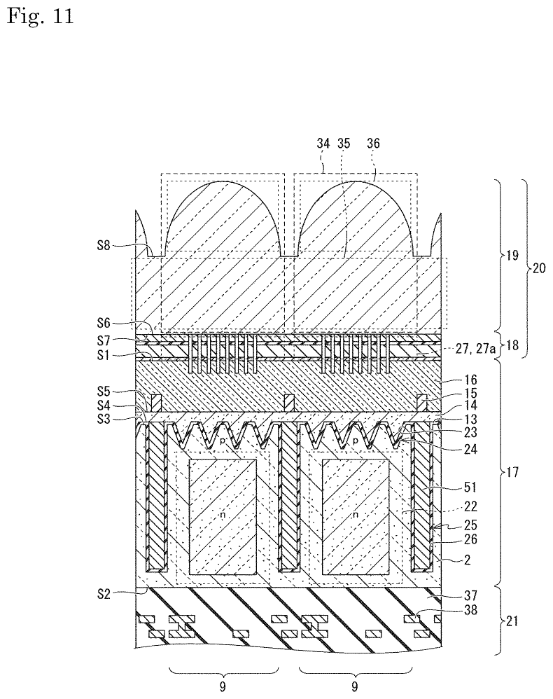

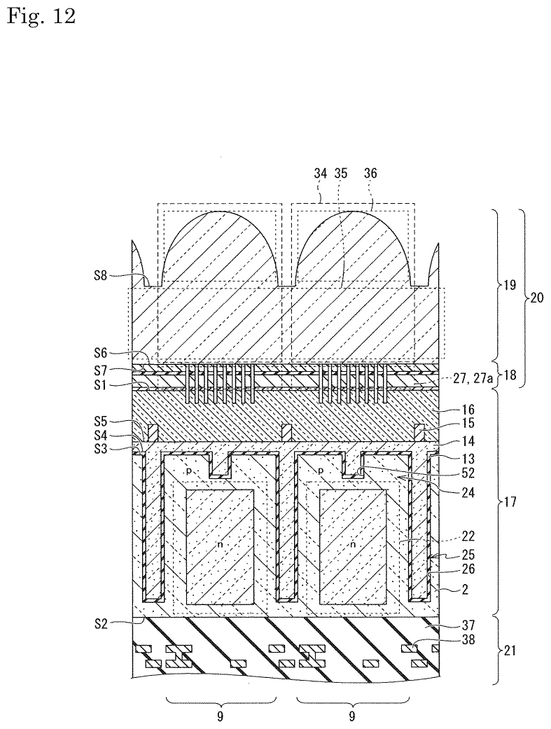

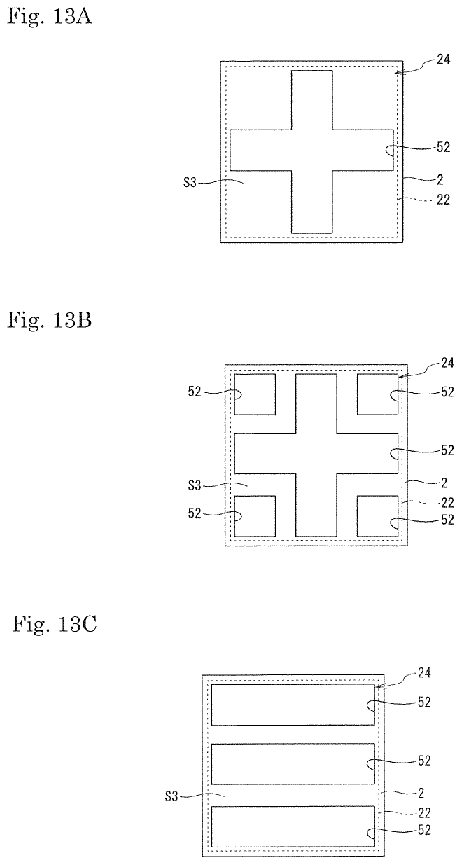

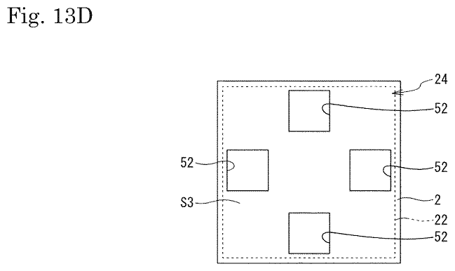

Hence, according to the microlens 34, the refractive index of the microlens 34>the refractive index of air holds, and therefore the speed (phase speed) of light having been incident on the microlens 34 becomes slower than the speed of light traveling in air, and a phase difference La is produced. Then, since there is the phase difference La of the light at a boundary between the protrusion portion 48 and the recess portion 49 of the microlens 34, an equiphase plane is bent, and incident light travels while being eventually condensed in a center direction of the protrusion portion 48. That is, the microlens 34 does not bend and condense the incident light, but condenses light using a phase difference of the light.
(4) In addition, for example, a configuration may be employed where a shape formed by periodically disposing a plurality of microstructures 50 is used as the shape of the lens-shaped portion 36 as illustrated in FIG. 10 (metalens). For example, the shape includes the plurality of microstructures 50 (hereinafter, also referred to as “nano-pillars 50”) vertically provided on the bottom portion 35. The bottom portion 35 and the nano-pillars 50 form a metasurface structure. The nano-pillar 50 is disposed such that the nano-pillar 50 modulates the phase of light passing through the microlens 34, and such a phase distribution is obtained that incident light on the microlens 34 is condensed. That is, the microlens 34 does not bend and condense the incident light, but condenses light using a phase difference of the light. As the shape of the nano-pillar 50, for example, a nanofin shape of a rotational symmetrical shape such as a circular columnar shape or an asymmetrical shape such as a regular rectangular prism shape can be adopted. Furthermore, the height of the nano-pillar 50 is, for example, approximately 100 nm to 1000 nm, and the diameter is, for example, approximately 50 nm to 700 nm.
(5) In addition, although the first embodiment has described the example where the material having the water vapor barrier property is used as the material of the microlens array 19 and the silicon nitride (SiN), the silicon oxynitride (SiON), or the silicon carbonitride (SiCN) is used as the material having the water vapor barrier property, other configurations can be also adopted. For example, there may be employed a configuration where a high refractive index resin having a refractive index equal to or more than 1.6 is used as the material having the water vapor barrier property. A high refractive index resin having a refractive index, more preferably, equal to or more than 1.7 and, still more preferably, equal to or more than 1.8 is used. For example, an acrylic resin that contains an inorganic pigment or the like to increase the refractive index can be adopted. Here, since the high refractive index resin contains the inorganic pigment or the like, the high refractive index resin has a high density of the material. Consequently, by using the high refractive index resin as the materials of the bottom portion 35 and the lens-shaped portion 36, it is possible to improve the water vapor barrier property. Furthermore, the refractive index increases, so that it is possible to improve condensation performance of the microlens 34, reduce the thickness of the microlens 34, and further prevent the height of the layer (upper layer) located on the light receiving surface side of the optical element 27 from becoming higher.
(6) In addition, for example, there may be employed a configuration where amorphous silicon is used as the material having the water vapor barrier property. Here, amorphous silicon is a material whose density and refractive index are higher than those of crystalline silicon. Consequently, by using amorphous silicon as the materials of the bottom portion 35 and the lens-shaped portion 36, it is possible to improve the water vapor barrier property. Furthermore, the refractive index increases, so that it is possible to improve condensation performance of the microlens 34, reduce the thickness of the microlens 34, and further prevent the height of the layer (upper layer) located on the light receiving surface side of the optical element 27 from becoming higher.
(7) In addition, although the first embodiment has described an example where the insulating film 14 is disposed in the trench portion 26 covered with the pinning film 13, other configurations may be adopted. There may be employed a configuration where a metal light shielding film 51 is disposed in the trench portion 26 as illustrated in, for example, FIG. 11. As a material of the metal light shielding film 51, for example, aluminum (Al) or silver (Ag) can be adopted. Consequently, when light having been incident on the photoelectric conversion unit 22 enters the pixel separating portion 25, it is possible to reflect the entering light in the metal light shielding film 51, and suppress photomixing caused when the light transmits through the pixel separating portion 25. In addition, when the water vapor barrier property of the microlens array 19 allows air to transmit through the microlens 34 from the light receiving surface side of the microlens 34 and enter the wire grid polarizer 27a side, it is possible to reduce moisture contained in the entering air, and suppress corrosion of the metal light shielding film 51 due to the moisture.
(8) Although the first embodiment has described the example where the structure that the recess portions 23 of the inverted pyramidal shapes are disposed as the light diffusion structure 24 in the two-dimensional array, other configurations can be also adopted. As illustrated in, for example, FIGS. 12, 13A, 13B, 13C, and 13D, a structure including a groove portion 52 including an opening portion in the rear surface S3 of the substrate 2 can be adopted as the light diffusion structure 24. FIG. 13A illustrates a case where the shape of the opening portion of the groove portion 52 is a cross shape, FIG. 13B illustrates a case where the shape of the opening portion of the groove portion 52 includes a cross and dots disposed in respective upper right, upper left, lower right, and lower left spaces of the cross, FIG. 13C illustrates a case where the shape of the opening portion of the groove portion 52 is a III shape of a Roman number, and FIG. 13D illustrates a case where the shape of the opening portion of the groove portion 52 is a shape including dots disposed on upper, lower, left, and right sides.

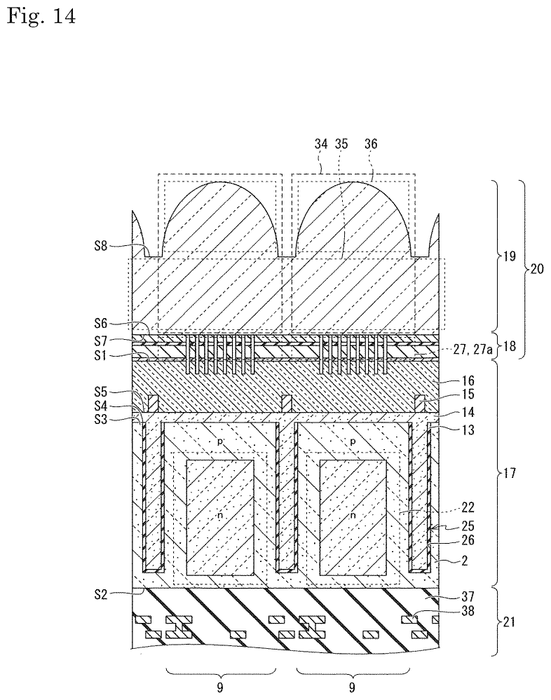

Furthermore, there may be employed a configuration that does not include the light diffusion structure 24 as illustrated in, for example, FIG. 14.
(9) In addition, the present technology can be applied to general light detecting devices including not only a solid-state imaging device that is the above-described image sensor, but also a distance measuring sensor that is also called a Time of Flight (ToF) sensor and measures a distance. The distance measuring sensor is a sensor that emits irradiation light to an object, detects reflective light acquired by reflecting the irradiation light on the surface of the object and has returned, and calculates a distance to the object on the basis of a flight time until the reflective light is received after emission of the irradiation light.

### 2. Second Embodiment: Example of Application to Electronic Device

The technology according to the present disclosure (present technology) may be applied to various electronic devices.

FIG. 15 is a diagram illustrating an example of a schematic configuration of an imaging device (such as a video camera and a digital still camera) as an electronic device to which the present technology is applied.

As illustrated in FIG. 15, an imaging device 1000 includes the lens group 1001, the solid-state imaging device 1002 (the solid-state imaging device 1 according to the first embodiment), a Digital Signal Processor (DSP) circuit 1003, a frame memory 1004, a monitor 1005, and a memory 1006. The DSP circuit 1003, the frame memory 1004, the monitor 1005, and the memory 1006 are connected to one another via a bus line 1007.

The lens group 1001 guides incident light (image light) from a subject to the solid-state imaging device 1002, and forms a light receiving surface (pixel region) of the solid-state imaging device 1002.

The solid-state imaging device 1002 includes a CMOS image sensor according to the above-described first embodiment. The solid-state imaging device 1002 converts a light amount of the incident light formed on the light receiving surface by the lens group 1001 into an electrical signal in the pixel unit, and supplies the electric signal as a pixel signal to the DSP circuit 1003. The DSP circuit 1003 performs predetermined image processing on the pixel signal supplied from the solid-state imaging device 1002. Furthermore, the DSP circuit 1003 supplies the image signal after image processing to the frame memory 1004 in the frame unit, and causes the frame memory 1004 to temporarily store the image signal.

For example, the monitor 1005 is constituted of a panel type display device such as a liquid crystal panel or an organic Electro Luminescence (EL) panel. The monitor 1005 displays an image (moving image) of a subject on the basis of the pixel signal in the frame unit temporarily stored in the frame memory 1004.

The memory 1006 is constituted of a DVD, a flash memory, or the like. The memory 1006 reads and stores the pixel signal in the frame unit temporarily stored in the frame memory 1004.

Note that the electronic device to which the solid-state imaging device 1 can be applied is not limited to the imaging device 1000, and can also be applied to other electronic devices. In addition, although there is employed a configuration where the solid-state imaging device 1 according to the first embodiment is used as the solid-state imaging device 1002, other configurations can be also adopted. For example, there may be employed a configuration where another light detecting device to which the present technology is applied such as the solid-state imaging device 1 according to the modification example of the first embodiment is used.

The present technology can be also configured as follows.
(1)

A light detecting device includes:
a substrate on which a plurality of photoelectric conversion units are formed; a plurality of optical elements that are disposed on a light receiving surface side of the substrate; and a microlens array that is disposed on a light receiving surface side of the plurality of optical elements, and includes a plurality of microlenses that guide incident light to the photoelectric conversion units, the optical element contains a metal material, and a surface on an optical element side of the microlens array is formed in contact with light receiving surfaces of the optical elements so as to cover the light receiving surfaces and also serve as a protection film that suppresses corrosion of the metal material.
(2)

In the light detecting device described in above (1), the optical element is a wire grid polarizer.
(3)

In the light detecting device described in above (2), the optical element includes a plurality of belt-shaped conductors that are disposed at a predetermined pitch, and includes a gap between the neighboring belt-shaped conductors.
(4)

In the light detecting device described in above (1), the optical element is a plasmon filter.
(5)

In the light detecting device described in above (1), the optical element is a Guided Mode Resonance (GMR) filter.
(6)

In the light detecting device described in any one of above (1) to (5), each of the plurality of microlenses has a structure that a bottom portion shared by the plurality of microlenses and a lens-shaped portion individually formed per microlens are laminated in this order on an optical element array including the plurality of optical elements.
(7)

In the light detecting device described in above (6), a shape of the lens-shaped portion is a planar protrusion type.
(8)

In the light detecting device described in above (6), a shape of the lens-shaped portion is a columnar type.
(9)

In the light detecting device described in above (6), a shape of the lens-shaped portion is a shape formed by periodically disposing a plurality of microstructures.
(10)

In the light detecting device described in any one of above (1) to (9), a material of the microlens array is a material having a water vapor barrier property.
(11)

In the light detecting device described in above (10), the material having the water vapor barrier property is silicon nitride, silicon oxynitride, or silicon carbonitride.
(12)

In the light detecting device described in above (10), the material having the water vapor barrier property is a high refractive index resin having a refractive index equal to or more than 1.6.
(13)

In the light detecting device described in above (10), the material having the water vapor barrier property is amorphous silicon.
(14)

The light detecting device described in any one of (1) to (13) further includes a pixel separating portion that is disposed between the neighboring photoelectric conversion units of the substrate, and includes a trench portion, and
the pixel separating portion includes a metal light shielding film disposed in the trench portion.
(15)

An electronic device includes a light detecting device, the light detecting device including: a substrate on which a plurality of photoelectric conversion units are formed; a plurality of optical elements that are disposed on a light receiving surface side of the substrate; and a microlens array that is disposed on a light receiving surface side of the plurality of optical elements, and includes a plurality of microlenses that guide incident light to the photoelectric conversion units, the optical element contains a metal material, and a surface on an optical element side of the microlens array is formed in contact with light receiving surfaces of the optical elements so as to cover the light receiving surfaces and also serve as a protection film that suppresses corrosion of the metal material.

### REFERENCE SIGNS LIST

1 Solid-state imaging device
2 Substrate
3 Pixel region
4 Vertical driving circuit
5 Column signal processing circuit
6 Horizontal driving circuit
7 Output circuit
8 Control circuit
9 Pixel
10 Pixel drive wiring
11 Vertical signal line
12 Horizontal signal line
13 Pinning film
14 Insulating film
15 Light shielding film
16 Flattening film
17 Light reception layer
18 Optical element array
19 Microlens array
20 Light condensation layer
21 Wiring layer
22 Photoelectric conversion unit
23 Recess portion
24 Light diffusion structure
25 Pixel separating portion
26 Trench portion
27 Optical element
27a Wire grid polarizer
27b Plasmon filter
27b Plasmon filter
27c GMR filter
28 Belt-shaped conductor
29 Gap
30 Light reflection layer
31 Insulating film
32 Light absorption layer
33 Adhesion layer
34 Microlens
35 Bottom portion
36 Lens-shaped portion
37 Insulating interlayer film
38 Wiring
39 Protection film
40 Light
41 First material film
42 Second material film
43 Hole
44 Metal film
45 Diffraction grating
46 Clad layer
47 Core layer
48 Protrusion portion
49 Recess portion
50 Microstructure (nano-pillar)
51 Metal light shielding film
52 Groove portion

What is claimed is:

1. A light detecting device, comprising:
a substrate on which a plurality of photoelectric conversion units are formed;
a plurality of optical elements that are disposed on a light receiving surface side of the substrate; and
a microlens array that is disposed on a light receiving surface side of the plurality of optical elements, and includes a plurality of microlenses that guide incident light to the photoelectric conversion units, wherein
the optical element contains a metal material, and
a surface on an optical element side of the microlens array is formed in contact with light receiving surfaces of the optical elements to cover the light receiving surfaces and also serve as a protection film that suppresses corrosion of the metal material.

2. The light detecting device according to claim 1, wherein the optical element is a wire grid polarizer.

3. The light detecting device according to claim 2, wherein the optical element includes a plurality of belt-shaped conductors that are disposed at a predetermined pitch, and includes a gap between the neighboring belt-shaped conductors.

4. The light detecting device according to claim 1, wherein the optical element is a plasmon filter.

5. The light detecting device according to claim 1, wherein the optical element is a Guided Mode Resonance (GMR) filter.

6. The light detecting device according to claim 1, wherein each of the plurality of microlenses has a structure that a bottom portion shared by the plurality of microlenses and a lens-shaped portion individually formed per microlens are laminated in this order on an optical element array including the plurality of optical elements.

7. The light detecting device according to claim 6, wherein a shape of the lens-shaped portion is a planar protrusion type.

8. The light detecting device according to claim 6, wherein a shape of the lens-shaped portion is a columnar type.

9. The light detecting device according to claim 6, wherein a shape of the lens-shaped portion is a shape formed by periodically disposing a plurality of microstructures.

10. The light detecting device according to claim 1, wherein a material of the microlens array is a material having a water vapor barrier property.

11. The light detecting device according to claim 10, wherein the material having the water vapor barrier property is silicon nitride, silicon oxynitride, or silicon carbonitride.

12. The light detecting device according to claim 10, wherein the material having the water vapor barrier property is a high refractive index resin having a refractive index equal to or more than 1.6.

13. The light detecting device according to claim 10, wherein the material having the water vapor barrier property is amorphous silicon.

14. The light detecting device according to claim 1, further comprising a pixel separating portion that is disposed between the neighboring photoelectric conversion units of the substrate, and includes a trench portion, and
wherein the pixel separating portion includes a metal light shielding film disposed in the trench portion.

15. An electronic device comprising a light detecting device, the light detecting device comprising:
a substrate on which a plurality of photoelectric conversion units are formed;
a plurality of optical elements that are disposed on a light receiving surface side of the substrate; and
a microlens array that is disposed on a light receiving surface side of the plurality of optical elements, and includes a plurality of microlenses that guide incident light to the photoelectric conversion units, wherein
the optical element contains a metal material, and
a surface on an optical element side of the microlens array is formed in contact with light receiving surfaces of the optical elements so as to cover the light receiving surfaces and also serve as a protection film that suppresses corrosion of the metal material.
